(19) United States
(12) Patent Application Publication
(10) Pub. No.: US 2013/0070426 A1
(43) Pub. Date: Mar. 21, 2013

(54) CONTROL DEVICE

(71) Applicants: Ralf Lippok, Backnang (DE); Markus Lux, Winnenden (DE); Eckhardt Philipp, Schwieberdingen (DE); Ibrahim Degirmenci, Budapest (HU); Stephan Luetzerath, Ludwigsburg (DE)

(72) Inventors: Ralf Lippok, Backnang (DE); Markus Lux, Winnenden (DE); Eckhardt Philipp, Schwieberdingen (DE); Ibrahim Degirmenci, Budapest (HU); Stephan Luetzerath, Ludwigsburg (DE)

(73) Assignee: ROBERT BOSCH GmbH, Stuttgart (DE)

(21) Appl. No.: 13/635,567

(22) PCT Filed: Feb. 9, 2011
(86) PCT No.: PCT/EP2011/051908

§ 371 Date: Dec. 3, 2012

(30) Foreign Application Priority Data
Mar. 17, 2010 (DE) 10 2010 002 947.5

(51) Int. Cl. H05K 5/06

(52) U.S. Cl. 361/730

(57) ABSTRACT

The invention relates to a control device (10a), comprising a housing unit (12a) and a circuit module (14a) which is arranged in the housing unit (12a) and has a circuit carrier (16a), at least one electric/electronic circuit unit (18a) mounted on the circuit carrier (16a) and at least one contact unit (20a) for the electric contact of the control device (10a) with other electric modules (22c). According to the invention, the housing unit (12a) comprises a protective compound which surrounds the circuit module (14a) leaving open at least one region (24a) that is enclosed by the protective composition, on which region the at least one contact unit (20a) is arranged.

### BACKGROUND OF THE INVENTION

The invention is based on a control device.

Control devices are universally known for controlling a wide variety of functions and equipment and are increasingly used in the automotive field for controlling a wide variety of operations in a motor vehicle. Said control devices are available in a wide range of mechanical embodiments. A control device typically consists of a circuit module which is arranged in a housing unit that normally consists of a top cover and base. The circuit module comprises a circuit carrier which is frequently embodied as a printed circuit board and on which at least one electric/electronic circuit unit and contact units for the electric contact of the control device to other electric modules are arranged. The contact units are typically embodied as so-called male multipoint connectors, via which the printed circuit board can, for example, be contacted to a wiring harness.

In the first publication of the German patent application DE 44 43 501 A1, a control unit comprising a sealable housing unit is, for example, described. The housing unit serves to accommodate a circuit module which comprises a circuit carrier that is embodied as a printed circuit board and is equipped with all components required for the operation of the control device. The housing unit comprises a first housing part, which is fixedly connected to an electromagnetic arrangement, and a second housing part which can be moved away from the fixed housing part. Contact units, which are embodied as male multipoint connectors, are provided on the moveable housing part of the housing unit for the electric contact of the printed circuit board of the control device to other electric modules.

### SUMMARY OF THE INVENTION

The inventive control device has in contrast the advantage that the housing unit comprises a protective compound which surrounds the circuit module leaving open at least one region that is enclosed by the protective composition, on which region the at least one contact unit is arranged.

Embodiments of the present invention thus fulfill two essential points. On the one hand, the inventive embodiments provide the protection of the circuit carrier and the modules thereof from external influences as, for example, temperature, dirt and/or water, and on the other hand said embodiments provide the possibility for the direct contact of the circuit carrier with other electric modules as, for example, a wiring harness. By surrounding said assembled circuit carrier with a protective compound preferably embodied as a molding compound, several of the otherwise usual production steps can be omitted, whereby costs can be saved in an advantageous manner. When surrounding the circuit carrier with the molding compound, the assembled circuit carrier is directly extrusion coated with a plastic layer, whereby the otherwise usual housing components, such as the bottom housing part and the top housing part, are eliminated. In this connection, several assembly steps are omitted in the production process. Said steps would include supply of the housing components, fastening the circuit carrier in the bottom housing part, applying a seal which is effective between the housing top part and the housing bottom part, attaching the housing top part to the housing bottom part and fastening the two housing components to each other. By means of the possibility of directly contacting the circuit carrier, for example, with the wiring harness, an additional contacting unit as, for example, a male multipoint connector can be omitted. In so doing, the manufacturing costs for a control device can be advantageously reduced. The result is a compact, comparatively small control device that is well protected from environmental influences.

Particularly advantageous is the fact that the control device has at least one contacting device, which is associated with the at least one recessed region, and comprises a sealing unit for sealing the circuit module and at least one contact element for contacting with the at least one contact unit. In this case, the recess provided in the protective compound has an edging surrounding the same. The edging surrounding said recess is especially formed from the protective compound. The edging thereby comprises a surface that is suitable for sealing the contact elements or respectively the circuit module, said surface being brought into operative connection with the sealing element. In this way, a reliable electric contacting of the circuit carrier and the other modules is advantageously ensured in a simple and cost effective manner.

In an advantageous embodiment of the control device according to the invention, the sealing of the circuit module takes place via the contacting device on an external surface of the housing unit and/or on a lateral surface of the at least one recessed region, in particular on the closed edging of the recess which is formed in this region. In an advantageous manner, the inventive casing of the circuit module of the control device facilitates a sealing of the circuit module on the external surface of the housing unit. These two surfaces can, for example, be engineered very precisely and with a high surface quality during molding, which leads to a good sealing. Due to the embodiment of the housing unit according to the invention, the mounting of a seal which is effective between the housing bottom part and the housing top part is particularly omitted. A further option for sealing consists of sealing the circuit module on a lateral surface of the recessed region. In so doing, the contacting device to be placed in the recess can be designed wedge-shaped. At least in a region starting from the external surface of the housing unit, the edging of the recess that has been formed is accordingly configured diagonally sloping in the direction of the contact elements of the circuit module. In order to ensure good contacting, it is useful for the contact elements of the contacting device to always be set or pushed down with the same force onto the contact units which are preferably designed as lands. In order to do this, it is necessary for the spacing between the external surfaces of the housing unit, i.e. the distance between the upper edge and the lower edge of the housing unit, and therefore also the length of the contact elements to be constant. The thickness of the circuit carrier is however typically not constant and can fluctuate to a certain degree. This disadvantage is resolved by the sealing which takes place on the lateral surface of the recess, and therefore a constant spacing and thus a constant contact force are ensured.

In a further advantageous embodiment of the invention, a recess is associated with the at least one contact unit, wherein a common recess is associated with a plurality of contact units or a separate recess is associated with each contact unit. The design of the housing unit according to the invention facilitates in an advantageous manner different embodiments of the recesses, wherein the number, the size and the position of the recesses can be freely selected according to the requirements, i.e. as a function of the amount of space available and as a function of the regions on the circuit carrier, in which the contact units are arranged. In a first embodiment of the invention, the complete region of the circuit carrier, in which the contact units lie, is left open. In a second embodiment of the invention the free spaces between the contact units are additionally filled with protective compound so that nothing but the contact units are exposed. This so-called reach-through to the contact units can thereby preferably be designed as an elongated hole or as a bore. A ribbed design, which represents an intrusion protection for the contact units, advantageously results in this case, and therefore said contact units are protected from damage and/or touch. In particular, this embodiment still additionally offers advantages during the manufacturing process with regard to sealing and tolerance compensation in the molding tool. At the same time, a centering of the contacting device, which contacts the circuit carrier, in the recess or recesses of the housing unit can also occur.

In a further embodiment of the control device according to the invention, the contact units are arranged only on one side of the circuit carrier. The contact units are preferably arranged in at least one row on the circuit carrier. When manufacturing the control device, the equipped circuit carrier is enclosed with a protective compound preferably embodied as plastic, i.e. preferably insert molded with a thermosetting plastic. This molding process requires good sealing measures within the mold and to the contact units on the circuit carrier because the mold compound or respectively protective compound is typically a very low-viscosity compound, which can flow into the smallest gaps. The inventive positioning of the contact units on the circuit carrier makes it possible in an advantageous manner for the thickness tolerance of the circuit carrier, which in the case of standard circuit carriers typically amounts to ∀0.15 mm, not to have to be taken into account in the sealing concept of the molding tool. Because tolerances are an essential consideration in the construction, manufacture and assembly of components or products and the tolerances of each individual component can add up when assembling a plurality of parts causing an unfavorable tolerance chain to form, it is important to keep the tolerances as small as possible. The smaller however the tolerances are selected the more complex and therefore more expensive the manufacture of the corresponding part becomes. In this regard, the tolerances of a circuit carrier present a challenge for the construction and the entire component. The base material of a circuit carrier for a control device has, for example, a thickness of approximately 1.6 mm. The tolerance in this instance is considerably more than 0.1 mm upwards or downwards. The standard circuit carrier typically used has therefore a thickness tolerance of approximately ∀0.15 mm. If a circuit carrier having a standard layout would now be used, the molding tool would have to compensate the thickness tolerances of the circuit carrier. Due to the aforementioned low viscosity of the molding material, very high demands are placed on the molding tool. Tests have shown that alone the height difference amounting to approximately 50 μm from the upper edge of the circuit carrier base to the upper edge of the contact units that are designed as lands is sufficient to cause the molding compound to run out between the lands. A so-called bleeding and flashing refer to this event. As a result of the contact units being now positioned on one side of the circuit carrier, the molding tool no longer has to compensate the tolerances and significantly improved molding results can be achieved. This embodiment of the control device especially ensures a sufficient contact force when contacting the circuit carrier with other electric modules. By virtue of the fact that the contact units are arranged only on one side of the circuit carrier, the tolerance of the circuit carrier thickness does not have to be compensated during said contacting with other electric modules. The system or rather the device for contacting—irrespective of whether it relates in this instance to a conventional male multipoint connector or a direct plug system, respectively a direct plug connection—can thus be designed in a considerably simpler manner and thus in a more cost effective way.

The contact units consisting of two adjacent rows are arranged in a preferred manner offset to one another on the circuit carrier. Particularly advantageous is the fact that a good unbundling of individual conducting paths of the circuit units is thereby possible.

In a further advantageous embodiment of the control device according to the invention, the contacting device comprises a housing equipped with contact elements. The housing has at least two housing elements which can be moved relative to one another and which accommodate the control device at least partially between themselves. In an advantageous way, this results in a compact construction of the entire arrangement consisting of control device and contacting device. By the control device being virtually “swallowed” up by the contacting device, said arrangement consisting of control device and contacting device is overall smaller in structure than a serial arrangement consisting of control device and classic plug concept. A simple and reliable fixation of the contacting device vis-à-vis the control device results in a preferred manner, in particular with respect to vibrational stresses which occur.

In a further advantageous embodiment of the contacting device, the housing elements are designed such that they can pivot with respect to one another via a pivot joint. In another advantageous embodiment of the contacting device, the housing elements can be fixed relative to each other by means of a snap-on connection device. In an advantageous manner, a simple and reliable fixation of the contacting device on the control device thereby results with respect to vibrational stresses. In so doing, additional movable parts such as, for example, sliders or additional pivot levers can be advantageously omitted.

In a further advantageous embodiment of the contacting device, the contact elements comprise connector blocks which are arranged on an interior side of at least one housing element and on which spring-loaded contact bodies are disposed. In an advantageous manner, the control device is reliably retained in the closed contacting device. The sealing units of the contacting device reliably perform a sealing function on the molded surface of the control device and the resilient contact bodies rest safely on the contact units of the circuit carrier. In summary, the result is a reliable direct electric contacting of a circuit carrier with other electric modules, which is sealed off towards the outside. The housing elements of the contacting device, which can pivot relative to one another, make it possible to reliably avoid a frictional stress on the electric contacting surfaces during the assembly of the control device and the contacting device.

### BRIEF DESCRIPTION OF THE DRAWINGS

Exemplary embodiments of the invention are depicted in the drawings and are explained in detail in the following description.

FIG. 1 shows a perspective depiction of a first exemplary embodiment of a control unit according to the invention which includes a housing unit and a circuit module comprising contact units that is disposed in the housing unit, said contact units being arranged on the circuit carrier of the circuit module in a region of the housing which is left open from the protective compound.

FIG. 2 shows a cross-sectional depiction of the control unit from FIG. 1 comprising a first exemplary embodiment of a contacting device, which is associated with a recess and comprises a sealing unit as well as contact elements, wherein the sealing takes place on an external surface of the housing unit.

FIG. 3 shows a cross-sectional depiction of the control unit from FIG. 1 comprising a second exemplary embodiment of a contacting device, which is associated with a recess and comprises a sealing unit as well as contact elements, wherein the sealing takes place on a lateral surface of the recess.

FIG. 4 shows a cross-sectional depiction of a third exemplary embodiment of a control device, in which the contact units are arranged only on an upper side of the circuit carrier.

FIG. 5 shows a schematic top view of a recess of the housing of the control device from FIG. 4 including the contact units arranged on the upper side of the circuit carrier.

FIGS. 6 to 15 show different schematic depictions of a fourth exemplary embodiment of a control device according to the invention, wherein a contacting device is provided, which comprises a housing equipped with contact elements, said housing having at least two housing elements for accommodating the control device between them.

FIG. 6 shows from below a schematic view of a housing element of the contacting device.

FIG. 7 shows a schematic cross-sectional depiction of the housing element of the contacting device from FIG. 6.

FIG. 8 shows a schematic top view of the housing element of the contacting device from FIG. 6.

FIG. 9 shows a schematic side view of the fourth exemplary embodiment of a control device according to the invention, which can be received between the housing elements of the contacting device from FIGS. 6 to 8.

FIG. 10 shows a schematic partial cross-sectional depiction of the fourth exemplary embodiment of a control unit according to the invention from FIG. 9.

FIG. 11 shows a schematic top view of the fourth exemplary embodiment of a control device according to the invention from FIG. 9.

FIGS. 12 to 15 show the sequence of inserting the fourth exemplary embodiment of the control device according to the invention into the contacting device and the two housing elements being locked into place.

### DETAILED DESCRIPTION

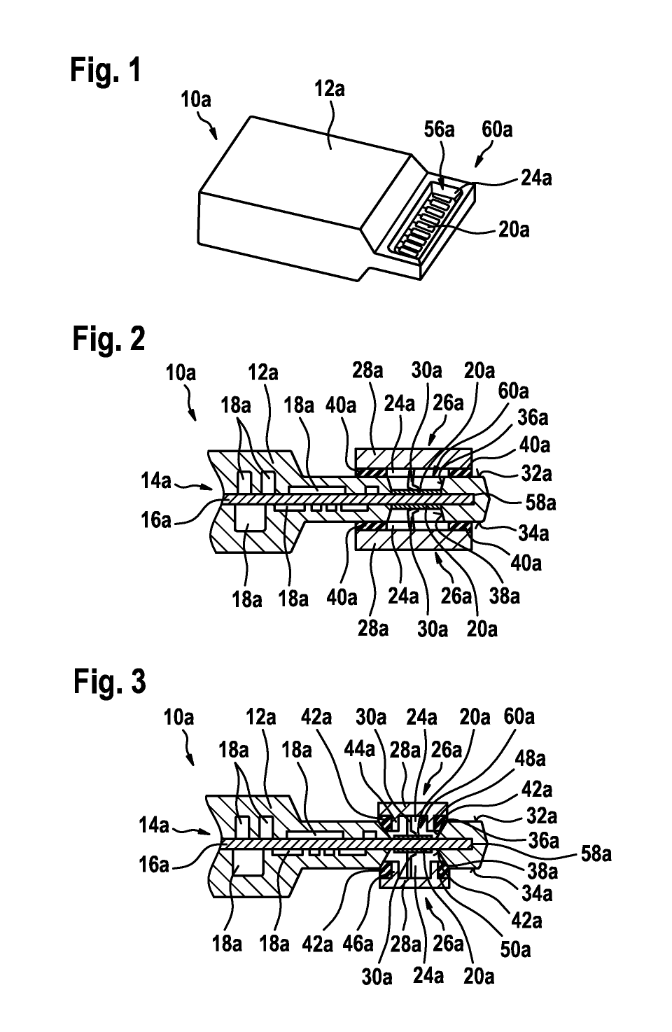

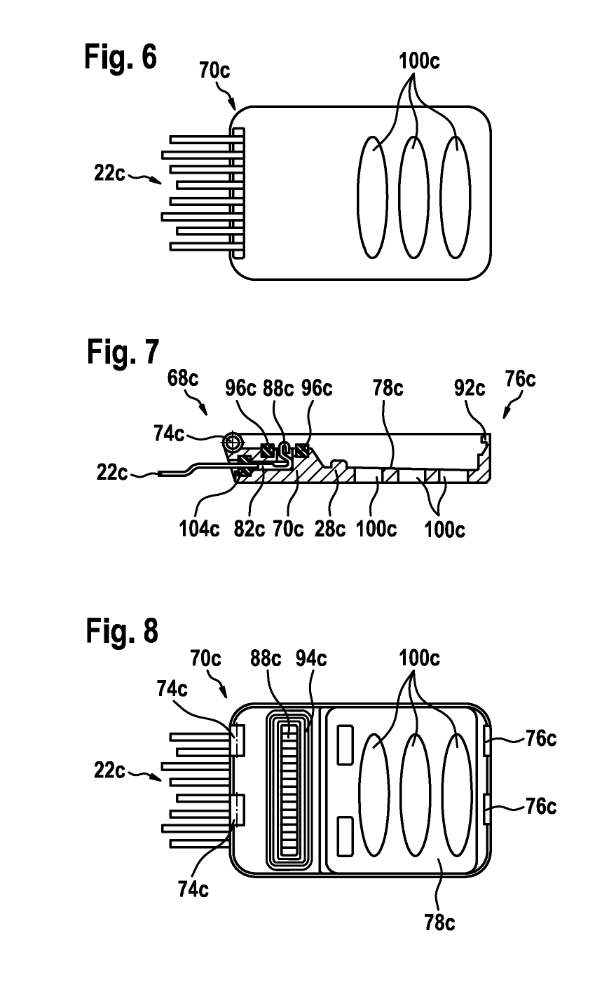

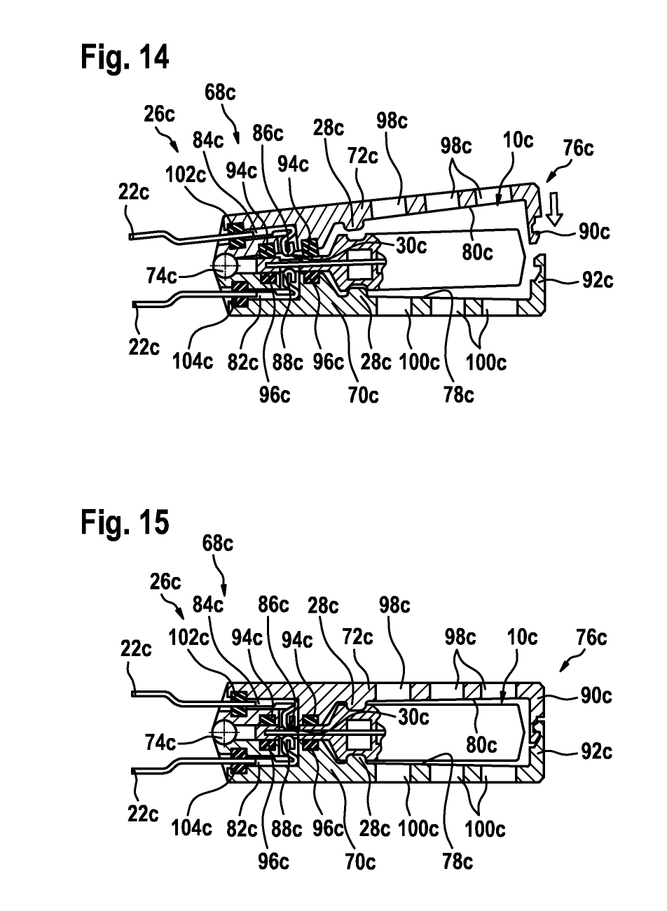

As can be seen from FIGS. 1 to 4 and 9 to 15, a control unit 10a, 10b, 10c, in particular for a motor vehicle, comprises a housing unit 12a, 12b, 12c and a circuit module 14a, 14b, and 14c disposed in the housing unit 12a, 12b, 12c. As can be seen in FIGS. 2 to 4, 10 and 12 to 15, the circuit module 14a, 14b, 14c comprises a circuit carrier 16a, 16b, 16c, on or to which at least one electric/electronic circuit unit 18a, 18b, 18c and a plurality of contact units 20a, 20b, 20c are mounted or applied for the electric contacting of the control device 10a, 10b, 10c, which is preferably embodied as an engine control unit, to other electric modules 22c, which are visible in FIGS. 6 to 8 and 12 to 15. In the present examples of embodiment, the circuit carrier 16a, 16b, 16c is preferably of plate-type design and in outline preferably of rectangular design, wherein other shapes are also conceivable.

The circuit carrier 16a, 16b, 16c preferably comprises a printed circuit board and/or a substrate, which, for example, is designed as a plastic substrate or as a ceramic substrate. The contact units 20a, 20b, 20c or the contacting points of the circuit carrier 16a, 16b, 16c are designed as lands or as small contact plates. In order to improve the contact properties, the contact units 20a, 20b, 20c can advantageously be designed having a gold surface.

In order on the one hand to protect the circuit carrier 16a, 16b, 16c and the modules 18a, 18b, 18c, 20a, 20b, 20c thereof from outside influences and on the other hand to facilitate a direct contact of the circuit carrier 16a, 16b, 16c with the other electric modules 22c, provision is made according to the invention for the housing unit 12a, 12b, 12c to comprise a protective compound, which surrounds the circuit module 14a, 14b, 14c leaving open at least one of the regions 24a, 24b, 24c enclosed by the protective composition, on which region the at least one contact unit 20a, 20b, 20c is arranged. The recess, for which provision is made, forms an edging which surrounds the same. In so doing, the edging itself is formed from the protective compound.

When manufacturing the housing unit 12a, 12b, 12c, the circuit module 14a, 14b, 14c is cast using a hard molding compound or a thermosetting plastic, for example, is insert molded by a thermal transfer molding process.

This means that the assembled circuit carrier 16a, 16b, 16c is enclosed with a plastic material 12a, 12b, 12c, preferably encapsulated with a thermosetting plastic. The circuit carrier 16a, 16b, 16c is thereby enclosed in plastic 12a, 12b, 12c such that only the contact units or lands 20a, 20b, 20c are exposed.

In order to contact the circuit carrier 16a, 16b, 16c with other electric modules 22c, at least one contacting device 26a, 26b, 26c associated with the recess 24a, 24b, 24c is provided.

As can be seen in FIGS. 1 to 4 and 12 to 15, the contacting device 26a, 26b, 26c comprises a sealing unit 28a, 28b, 28c for sealing the circuit module 14a, 14b, 14c and contact elements 30a, 30b, 30c for contacting with the contact units 20a, 20b, 20c. The sealing of the circuit module 14a, 14b, 14c via the contacting device 26a, 26b, 26c can take place on the external surface 32a, 32b, 32c of the housing unit 12a, 12b, 12c and/or on a lateral surface 36a, 38a of the recess 24a.

In a present first exemplary embodiment pursuant to FIGS. 1 and 2, a first contacting device 26a comprising a sealing unit 28a is disposed on an upper external surface 32a of the housing unit 12a and a second contacting device 26a comprising a sealing unit 28a on a lower external surface 34a of the housing unit 12a.

In a present second exemplary embodiment pursuant to FIG. 3, the sealing takes place on the lateral surface 36a, 38a of the recess 24a by means of the sealing unit 28a of the contacting device 26a having a collar 44a, 46a which is directed into the recess 24a and bears with the external surface 48a, 50a thereof against the lateral surface 36a, 38a of said recess 24a preferably while interposing a gasket 42a.

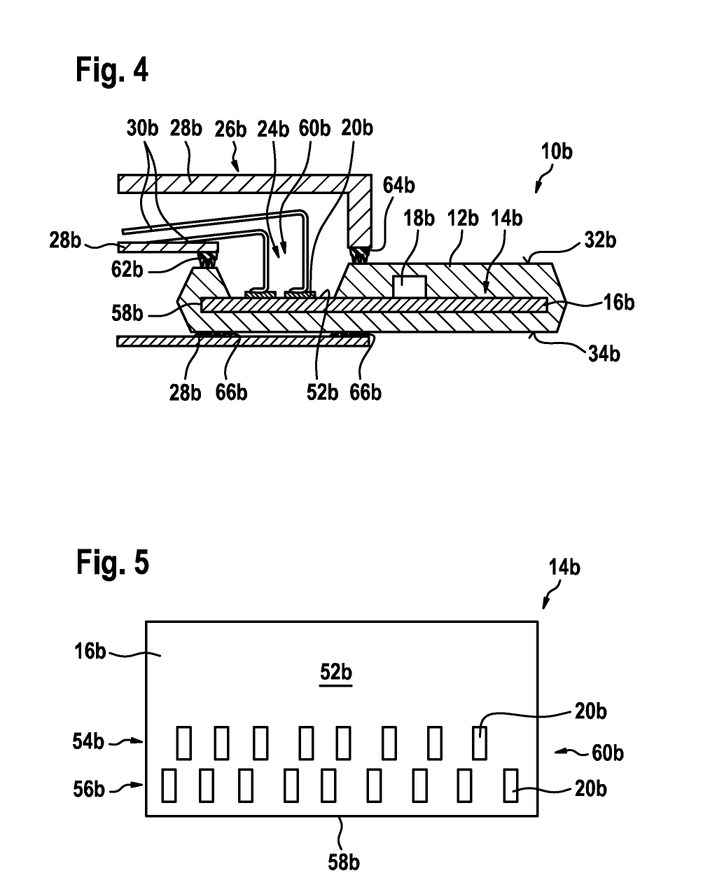

In a present third exemplary embodiment pursuant to FIGS. 4 and 5, a first contacting device 26b is disposed having a first sealing unit 28b on an upper external surface 32b of the housing unit 12b and having a second sealing unit 28b on a lower external surface 34b of the housing unit 12b.

In a present fourth exemplary embodiment pursuant to FIGS. 6 to 15, a first contacting device 26c is disposed having a sealing unit 28c likewise on an upper external surface 32c of the housing unit 12c and a second contacting device 26c having a sealing unit 28c on a lower external surface 34c of the housing unit 12c.

In FIGS. 2 and 4 as well as 12 to 15, the sealing takes place on the external surfaces 32a, 32b, 32c, 34a, 34b, 34c of the housing unit 12a, 12b, 12c by the sealing unit 28a, 28b, 28c of the contacting device 26a, 26b, 26c resting on the external surfaces 32a, 32b, 32c, 34a, 34b, 34c preferably while interposing a separate gasket 20a, 62b, 64b, 66b, 94c, 96c.

In the present exemplary embodiments, a common recess 24a, 24b, 24c is associated with the contact units 20a, 20b, 20c, said recess facilitating a so-called reach-through or access to the contact units 20a, 20b, 20c preferably from the top side as well as from the bottom side of the control device 10a, 10b, 10c. The first contacting device 26a pursuant to FIGS. 1 to 3 is disposed on the upper external surface 32a of the housing unit 12a and the second contacting device 2a on the lower external surface 34a of said housing unit 12a. The contacting device 26b is disposed on the upper external surface 32b of the housing unit 12b. In alternative embodiments which are not depicted, a separate recess can however also be associated with each contact unit.

FIGS. 4 and 5 show the third exemplary embodiment of a control device 10b according to the invention. In order to optimize the molding process, the contact units 20b are disposed only on one side 52b, preferably on the upper side of the circuit carrier 16b. This means that all contact units 20b are disposed on the same side 52b of the circuit carrier 16b in this embodiment. In so doing, the reliability of the molding process can be increased, molding tool costs can be decreased and the waste can be held as low as possible.

The distance of the upper surface of the contact units 20b to the upper surface of the housing unit 12b or respectively the control device 10b, i.e. the so-called contact distance, and the thickness of the entire control device 10b as well as the evenness of the surfaces on the control device 10b on which sealing takes place are essential functional dimensions of the complete control device 10b. Because the contact units 20b lie only on one side 52b of the circuit carrier 16b, said circuit carrier 16b can be placed into the molding tool such that the tolerance of the thickness of the circuit carrier 16b has no influence on the so-called contact distance. Hence, the contacting of the circuit carrier 16b or respectively the control device 10b can be configured with further electric modules because said contacting does not have to compensate the aforementioned tolerance. A system or a device 26b for contacting—irrespective of whether it relates in this instance to a conventional male multipoint connector or a direct plug system, respectively a direct plug connection—can consequently be considerably more easily configured and therefore more cost effectively designed.

In all of the embodiments of the control device 10a, 10b, 10c, the contact units 20a, 20b, 20c can be arranged in a row as well as in a plurality of rows 54b, 56a, 56b on the circuit carrier 16a, 16b, 16c. The contact units 20b arranged in two adjacent rows 54b, 56b on the circuit carrier 16b are preferably arranged offset relative to each other.

In all of the embodiments of the control device 10a, 10b, 10c, the contact units 20a, 20b, 20c are arranged in a particularly preferred manner in a region 60a, 60b, 60c on the circuit carrier 16a, 16b, 16c, which is close to the edge and is associated with an edge 58a, 58b, 58c of said circuit carrier 16a, 16b, 16c.

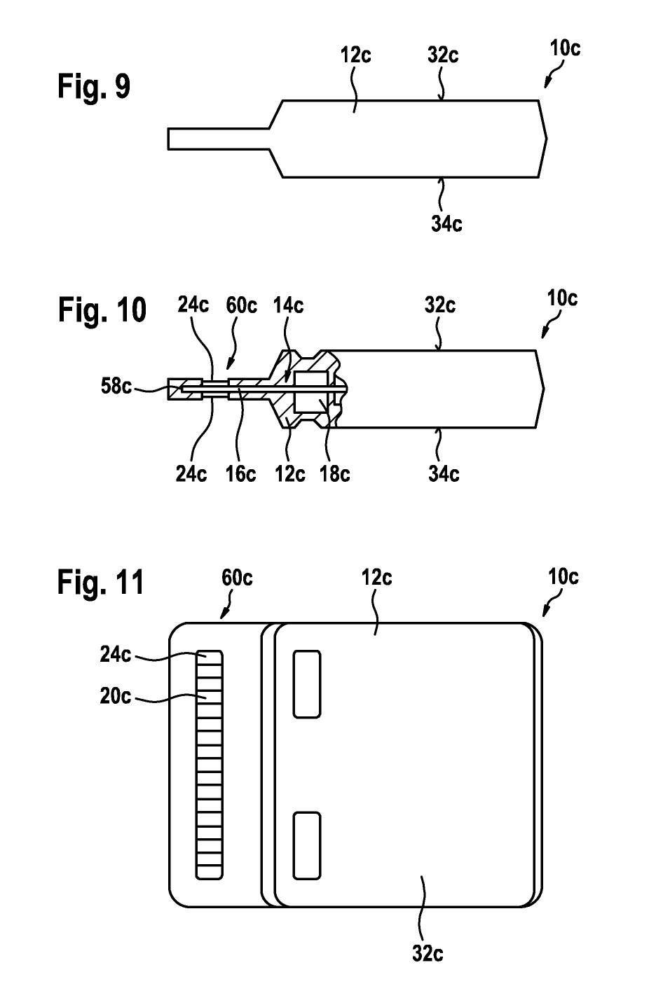

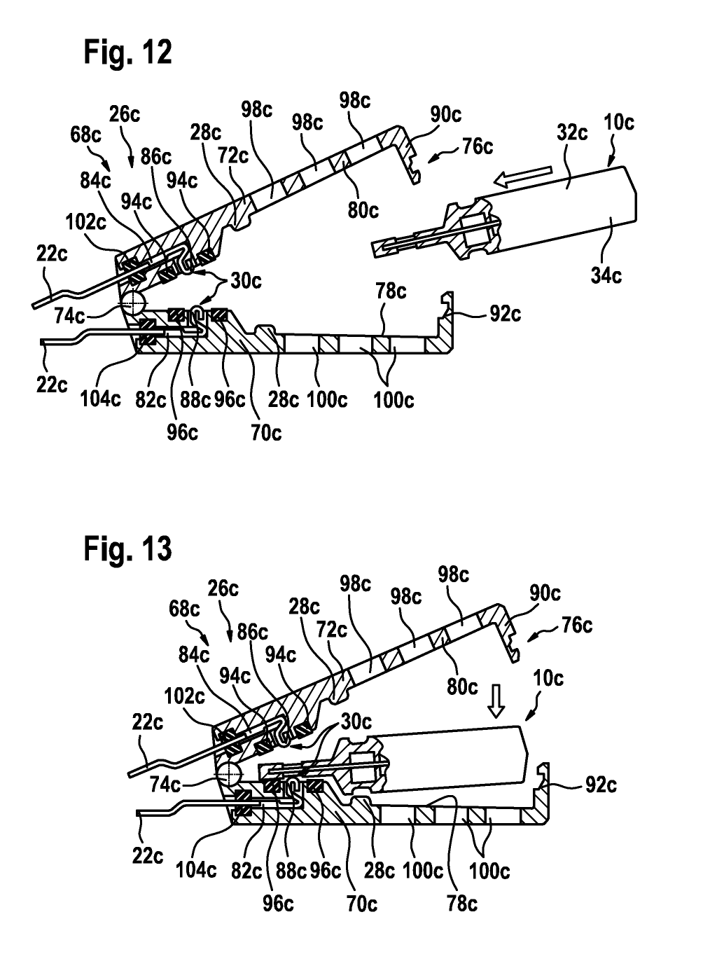

The FIGS. 6 to 15 show the fourth exemplary embodiment of a control device 10c according to the invention having a contacting device 26c, which comprises a housing 68c equipped with contact elements 30c. Said housing has at least two housing elements 70c, 72c which can be moved relative to one another and at least partially, preferably completely accommodate the control device 10c between themselves. In this connection, FIGS. 6 to 8 show the housing elements 70c, 72c and FIGS. 9 to 11 the control device 10c. Said housing elements 70c, 72c preferably have ventilation openings 98c and 100c. As can be seen in FIGS. 12 to 15, the encapsulated circuit module 14c or rather the control unit 10c can be at least partially and preferably completely accommodated between said two housing elements 70c, 72c of the contacting device 26c, said housing elements being arranged so that they can be moved approximately relative to one another or rather so that they move relative to one another. The relative movability of said housing elements 70c, 72c can, for example, be implemented by means of a pivot joint 74c, via which said two housing elements 70c, 72c can be pivoted relative to each other as is depicted in the present exemplary embodiment. In an alternative embodiment which is not depicted, the housing elements can, for example, be designed in the shape of a pot-lid arrangement, wherein the housing element designed as the lid can be withdrawn from the housing element designed as a pot. In an advantageous manner, said two housing elements 70c, 72c can be fixed relative to one another via a snap-on connection device depicted in FIGS. 7 and 12 to 15.

In the present exemplary embodiment, the two housing elements 70c, 72c of the contacting device 26c are preferably designed as two point-symmetrical half shells which can be connected to one another and meshed with one another on one side via the pivot joint 74c. In order to lock into place, the housing elements 70c, 72c have a snap-on connection device 76c, which comprises two snap-fit hooks 90c, 92c that can interlock with each other, on a side opposite to the pivot joint 74c.

For the purpose of contacting, the contact elements 30c comprise connector blocks 82c and 84c arranged on an interior side 78c, 80c of at least one housing element 70c, 72c and on which spring-loaded and/or resilient contact bodies 86c, 88c are disposed. This means that the housing elements 70c, 72c designed as half shells comprise in each case a connector block 82c and 84c, which run on the interior side 78c, 80c of the half shells 70c, 72c in the form of individually spring-loaded and/or resilient contact bodies 86c, 88c for direct contacting on the circuit carrier 16c. Around the contact bodies 86c, 88c and respectively the connector blocks 82c, 84c, a sealing element 94c, 96c designed as a face seal is preferably disposed in each case on the housing elements 70c, 72c acting as a sealing unit 28c, said sealing element protecting the contacting region by sealing off the surface or rather the external surface 32c, 34c of the control device 10c or respectively the housing unit 12c vis-à-vis the surroundings or against harmful environmental influences. It is preferred to have in each case a sealing element 102c, 104c disposed around the electric cables 22c connected to the connector blocks 82c, 84c.

As shown in FIGS. 12 to 14, the control device 10c can now be placed into the approximately opened arrangement of the half shells 70c, 72c. This means said control device 10c is placed into the preferably half opened contacting device 26c. In so doing, the sealing elements 94c, 96c and the spring-loaded and/or resilient contact bodies 86c, 88c are still unloaded. By the half shells 70c 72c being closed pursuant to FIG. 15, said spring-loaded and/or resilient contact bodies 86c, 88c are lowered from both sides onto the contact units 20c of the circuit carrier 16c, which units are designed as lands, while the sealing elements 94c, 96c fit snugly around the contact region on the surfaces or rather external surfaces 32c, 34c of the control device 10c or rather the housing unit 12c of said control device 10c. The half shells 70c, 72c are locked in place relative to one another. This means that a locked end position of said control device 10c results in the contacting device 26c. As a result of the elastic deformation of the half shells 70c, 72c, the contact forces in the inside of said contacting device 26c which are necessary for the contacting and sealing operation are applied and maintained.

1. A control device comprising a housing unit (12a, 12b, 12c) and a circuit module (14a, 14b, 14c) which is arranged in the housing unit (12a, 12b, 12c) and has a circuit carrier (16a, 16b, 16c), at least one electronic circuit unit (18a, 18b, 18c) mounted on the circuit carrier (16a, 16b, 16c) and at least one contact unit (20a, 20b, 20c) for electric contact of the control device (10a, 10b, 10c) with other electric modules (22c), characterized in that the housing unit (12a, 12b, 12c) comprises a protective compound which surrounds the circuit module (14a, 14b, 14c) leaving open at least one region (24a, 24b, 24c) that is enclosed by the protective composition, on which region the at least one contact unit (20a, 20b, 20c) is arranged.

2. The control device according to claim 1, characterized by at least one contacting device (26a, 26b, 26c), which is associated with the at least one recessed region (24a, 24b, 24c), and comprises a sealing unit (28a, 28b, 70c, 72c) for sealing the circuit module (14a, 14b, 14c) and at least one contact element (30a, 30b, 30c) for contacting with the at least one contact unit (20a, 20b, 20c).

3. The control device according to claim 1, characterized in that the sealing of the circuit module (14a, 14b, 14c) takes place via the contacting device (26a, 26b, 26c) on at least one of an external surface (32a, 32b, 32c, 34a, 34b, 34c) of the housing unit (12a, 12b, 12c) and on a lateral surface (36a, 38a) of the at least one recessed region (24a).

4. The control device according to claim 1, characterized in that a recess (24a, 24b, 24c) is associated with the at least one contact unit (20a, 20b, 20c), wherein a common recess (24a, 24b, 24c) is associated with a plurality of contact units (20a, 20b, 20c) or a separate recess (24a, 24b, 24c) is associated with each contact unit (20a, 20b, 20c).

5. The control device according to claim 1, characterized in that the at least one contact unit (20b) is arranged only on one side (52b) of the circuit carrier (16b).

6. The control device according to claim 1, characterized in that the contact units (20a, 20b) are arranged in at least one row (54b, 56a, 56b) on the circuit carrier (16a, 16b).

7. The control device according to claim 6, characterized in that the contact units (20b) of two adjacent rows (54b, 56b) are arranged offset in relation to each other on the circuit carrier (16b).

8. The control device according to claim 1, characterized in that the at least one contact unit (20a, 20b, 20c) is arranged in a region (60a, 60b, 60c) on the circuit carrier (16a 16b, 16c) which is close to an edge and is associated with an edge (58a, 58b, 58c) of said circuit carrier (16a, 16b, 16c).

9. The control device according to claim 1, characterized in that the contacting device (26a) comprises a housing (68c) provided with at least one contact element (30c), said housing having at least two housing elements (70c, 72c) which can be moved relative to each other and at least partially accommodate the control device (10c) between themselves.

10. The control device according to claim 9, characterized in that the housing elements (70c, 72c) of the contacting device (26c) can be pivoted in relation to each other via a pivot joint (74c).

11. The control device according to claim 9, characterized in that the housing elements (70c, 72c) can be fixed in relation to each other via a snap-on connection device (76c).

12. The control device according to claim 9, characterized in that the at least one contact element (30c) comprises connector blocks (82c, 84c) which are arranged on an interior side (78c, 80c) of the at least one housing element (70c, 72c) and on which at least one of spring-loaded contact bodies and/or resilient contact bodies (86c, 88c) are disposed.
